(19) United States
(12) Patent Application Publication
(10) Pub. No.: US 2013/0330472 A1
(43) Pub. Date: Dec. 12, 2013

(54) SUBSTRATE CONVEYANCE ROLLER, THIN FILM MANUFACTURING DEVICE AND THIN FILM MANUFACTURING METHOD

(71) Applicants: Kazuyoshi Honda, Osaka (JP); Sadayuki Okazaki, Osaka (JP); Noriaki Amo, Hyogo (JP); Noriyuki Uchida, Osaka (JP); Daisuke Suetsugu, Osaka (JP)

(72) Inventors: Kazuyoshi Honda, Osaka (JP); Sadayuki Okazaki, Osaka (JP); Noriaki Amo, Hyogo (JP); Noriyuki Uchida, Osaka (JP); Daisuke Suetsugu, Osaka (JP)

(73) Assignee: PANASONIC CORPORATION, Osaka (JP)

(21) Appl. No.: 14/000,551

(22) PCT Filed: Apr. 25, 2012
(86) PCT No.: PCT/JP2012/002847

§ 371 Date: Aug. 20, 2013

(30) Foreign Application Priority Data
Jun. 15, 2011 (JP) 2011-132964

(51) Int. Cl. C23C 16/458; B65G 13/00

(52) U.S. Cl. CPC C23C 16/458; B65G 13/00
USPC 427/248.1; 198/780; 118/50

(57) ABSTRACT

A substrate-conveying roller 6A is configured to convey a substrate under vacuum, and includes a first shell 11, an internal block 12, and a shaft 10. The first shell 11 has a cylindrical outer circumferential surface for supporting the substrate, and can rotate in synchronization with the substrate. The internal block 12 is disposed inside the first shell 11, and is blocked from rotating in synchronization with the substrate. The shaft 10 extends through, and supports the internal block 12. A clearance 15 is formed between the inner circumferential surface of the first shell 11 and the internal block 12. A gas is introduced into the clearance 15 from the internal block 12 toward the inner circumferential surface of the first shell 11.

### TECHNICAL FIELD

The present invention relates to substrate-conveying rollers, apparatuses for producing thin films, and methods for producing thin films.

### BACKGROUND ART

Thin-film technology is widely used for performance improvement and size reduction of devices. In addition, thin-film devices not only provide direct benefits to users, but also play an important role in environmental aspects, such as in protection of earth resources and in reduction of power consumption.

For advancement of such thin-film technology, it is essential to meet some requirements from the aspect of industrial use. That is, it is essential to achieve high efficiency, high stability, high productivity, and cost reduction of thin film production methods. Attempts are being made to meet such requirements.

A film formation technique that allows a high deposition rate is essential in order to increase the productivity of thin films. Increase in deposition rate is being pursued in thin film production that uses, for example, a vacuum evaporation method, a sputtering method, an ion plating method, or a CVD method (Chemical Vapor Deposition Method). A take-up type thin film production method is used as a method for continuously forming thin films in large numbers. In the take-up type thin film production method, an elongated substrate having been wound into a roll is unwound from an unwinding roller, a thin film is formed on the substrate being conveyed along a conveyance system, and the substrate is then wound on a winding roller. For example, thin films can be formed with high productivity by combining the take-up type thin film production method with a film formation source that allows a high deposition rate, such as a vacuum evaporation source using electron beam.

Factors that determine success and failure of such a continuous take-up type thin film production include thermal load during film formation, and cooling of the substrate. For example, in the case of vacuum evaporation, thermal radiation from a film formation source and thermal energy of evaporated atoms are applied to a substrate, and the temperature of the substrate is thus increased. Also in other film formation methods, although the heat source is different, thermal load is applied to a substrate during film formation. The substrate is cooled in order to prevent, for example, deformation and meltdown of the substrate from occurring due to such thermal load. The cooling is not necessarily carried out during film formation, and may be carried out in a region of a substrate-conveyance route other than the film formation region.

As means for cooling a slurry or the like with a roller in the atmosphere, Patent Literature 1 discloses a cooling roller including: a cylindrical body whose wall is provided with a plurality of slits or holes; and a partition plate provided in the cylindrical body. The cylindrical body can rotate relative to the partition plate in a sliding manner, and a coolant gas emitting pipe is provided in a space defined by the partition plate. With this cooling roller, a slurry can be sprayed with a large amount of the coolant gas, and thus can be cooled by removing heat directly from the slurry.

However, in a vacuum atmosphere, such a large amount of coolant gas as to allow direct removal of heat cannot be used in view of maintaining the vacuum. As an example of methods for cooling a substrate during film formation, there is a widely-used method in which a film is formed on a substrate extending along a cylindrical can disposed on a conveyance route of a conveyance system. With this method, heat can be released to the cooling can of large heat capacity by ensuring thermal contact between the substrate and the cylindrical can. Thus, increase in the temperature of the substrate can be prevented. In addition, the temperature of the substrate can be maintained at a specific cooling temperature. Cooling of the substrate by a cooling can is effective also in a region of the substrate-conveyance route other than the film formation region.

One of the methods for ensuring thermal contact between a substrate and a cylindrical can is a gas cooling method. Patent Literature 2 teaches that, in an apparatus for forming a thin film on a web serving as a substrate, a gas is introduced into a region between the web and supporting means. With this method, heat conduction between the web and the supporting means can be ensured, and thus increase in the temperature of the web can be suppressed.

Furthermore, long-time stability of equipment condition is required for stable industrial production of thin films.

### CITATION LIST

### Patent Literature

Patent Literature 1: JP S60 (1985)-184424 U
Patent Literature 2: JP H1 (1989)-152262 A
Patent Literature 3: JP 2010-7142 A

### SUMMARY OF INVENTION

### Technical Problem

When the take-up type thin film production is carried out for a long period of time, heat conduction from a substrate causes gradual accumulation of heat particularly in a substrate conveyance system along which the substrate having undergone film formation is conveyed. In general, a plurality of free rollers passively rotated by contact with a substrate are disposed in a conveyance system. Each free roller is generally composed of a central shaft and a roller shell connected to the central shaft via a bearing. Under vacuum, the degree of heat conduction between the substrate and the rollers is small. Therefore, the substrate passing through the rollers is cooled only slightly by each roller. However, since the rollers convey the substrate continuously, heat is progressively accumulated in the free rollers when film formation is performed for a long period of time. Accordingly, the temperature of the portion of the substrate conveyance system along which the substrate having undergone film formation is conveyed to a winding roller is increased, with the result that the substrate may be wrinkled on the conveyance route or the winding roller, or rotational failure may occur due to expansion of the free rollers.

In the case where a cooling roller in which a refrigerant is circulated is used as a conveying roller, tension control in the travelling system is complicated because of the need to drive the cooling roller. Patent Literature 3 discloses a cooling roller including: a hollow-cylindrical rotating body (roller body) that rotates in an outer circumferential direction of the cooling roller; circular plate-shaped cover members attached to the hollow-cylindrical rotating body so as to close openings at both ends in a length direction of the hollow-cylindrical rotating body; a rotation center shaft of the rotating body; and a cooling cylinder disposed in a hollow portion of the rotating body and being in non-contact with the rotating body. The rotation center shaft extends through the central portions of the cover members, and extends through the hollow portion of the rotating body. The rotation center shaft is attached to the cover members via bearings. The rotation center shaft is fixed and does not rotate. However, since the rotating member is configured to be driven to rotate, a free roller having cooling capability can be configured.

In order to allow stable industrial production of thin films, films of large width need to be formed under high vacuum at a high rate, and equipment condition needs to be kept stable for a long period of time. Thermal stabilization of the free rollers performed by gas introduction requires adjusting the amount of the gas introduced and using a roller configuration that can minimize the amount of the gas flowing out into a vacuum chamber.

An object of the present invention is to solve the aforementioned conventional problems, that is, to reduce increase in the temperature of a free roller in a substrate conveyance system with a small amount of gas introduced, and to increase the stability of equipment in long-time film formation.

### Solution to Problem

That is, the present disclosure provides a substrate-conveying roller that conveys a substrate under vacuum, the substrate-conveying roller including: a cylindrical first shell having a cylindrical outer circumferential surface for supporting the substrate, the cylindrical first shell being capable of rotating in synchronization with the substrate; an internal block disposed inside the first shell and blocked from rotating in synchronization with the substrate; and a shaft extending through, and supporting the internal block. In the substrate-conveying roller, a clearance is formed between an inner circumferential surface of the first shell and the internal block, and a gas is introduced into the clearance from the internal block toward the inner circumferential surface of the first shell.

### Advantageous Effects of Invention

According to the above substrate-conveying roller, the gas is introduced into the clearance between the inner circumferential surface of the first shell and the internal block. Therefore, heat accumulated in the first shell with the lapse of film formation time can be released to the internal block. Accordingly, heat accumulation and temperature increase in the first shell associated with the lapse of film formation time can be prevented. In addition, since the gas is introduced toward the inner circumferential surface of the first shell via the internal block, the introduced gas is allowed to contribute to cooling of the first shell without waste.

### BRIEF DESCRIPTION OF DRAWINGS

FIG. 1A is a schematic cross-sectional view of a substrate-conveying roller showing an example of one embodiment of the present invention.

FIG. 1B is a schematic cross-sectional view of the substrate-conveying roller of FIG. 1A, taken along a direction perpendicular to the axial direction of the substrate-conveying roller.

FIG. 1C is a schematic diagram showing a specific example of a leakage preventing structure.

FIG. 2A is a schematic cross-sectional view of a substrate-conveying roller showing another example of the one embodiment of the present invention.

FIG. 2B is a schematic cross-sectional view of the substrate-conveying roller of FIG. 2A, taken along a direction perpendicular to the axial direction of the substrate-conveying roller.

FIG. 3A is a schematic cross-sectional view of a substrate-conveying roller showing an example of another embodiment of the present invention.

FIG. 3B is a schematic cross-sectional view of the substrate-conveying roller of FIG. 3A, taken along a direction perpendicular to the axial direction of the substrate-conveying roller.

FIG. 4A is a schematic cross-sectional view of a substrate-conveying roller showing another example of the other embodiment of the present invention.

FIG. 4B is a schematic cross-sectional view of the substrate-conveying roller of FIG. 4A, taken along a direction perpendicular to the axial direction of the substrate-conveying roller.

FIG. 5A is a schematic cross-sectional view of a substrate-conveying roller showing an example of another embodiment of the present invention.

FIG. 5B is a schematic cross-sectional view of the substrate-conveying roller of FIG. 5A, taken along a direction perpendicular to the axial direction of the substrate-conveying roller.

FIG. 6A is a schematic cross-sectional view of a substrate-conveying roller showing an example of another embodiment of the present invention.

FIG. 6B is a schematic cross-sectional view of the substrate-conveying roller of FIG. 6A, taken along a direction perpendicular to the axial direction of the substrate-conveying roller.

FIG. 7A is a schematic cross-sectional view of a substrate-conveying roller showing an example of another embodiment of the present invention.

FIG. 7B is a schematic cross-sectional view of the substrate-conveying roller of FIG. 6A, taken along a direction perpendicular to the axial direction of the substrate-conveying roller.

FIG. 8 is a schematic view showing an example of an apparatus for producing thin films of the present invention.

FIG. 9 is a schematic view showing another example of an apparatus for producing thin films of the present invention.

### DESCRIPTION OF EMBODIMENTS

A first aspect provides a substrate-conveying roller that conveys a substrate under vacuum, the substrate-conveying roller including: a cylindrical first shell having a cylindrical outer circumferential surface for supporting the substrate, the cylindrical first shell being capable of rotating in synchronization with the substrate; an internal block disposed inside the first shell and blocked from rotating in synchronization with the substrate; a shaft extending through, and supporting the internal block; a clearance formed between an inner circumferential surface of the first shell and the internal block; and a gas channel for introducing a gas into the clearance from the internal block toward the inner circumferential surface of the first shell.

A second aspect provides the substrate-conveying roller as set forth in the first aspect, wherein a pressure in the clearance may be higher than a pressure outside the first shell. With this feature, the first shell can be cooled efficiently.

A third aspect provides the substrate-conveying roller as set forth in the first or second aspect, wherein a position at which the gas is introduced into the clearance from the internal block toward the inner circumferential surface of the first shell may be located in a central region in a width direction of the first shell. That is, the gas channel for introducing the gas into the clearance may be formed in a region containing the center of the first shell in the width direction of the first shell. In addition, the gas channel may be formed so that the central region in the width direction of the first shell is cooled with relatively high intensity, while the edge region in the width direction of the first shell is cooled with relatively low intensity. With this configuration, the first shell can be cooled uniformly in the width direction.

A fourth aspect provides the substrate-conveying roller as set forth in any one of the first to third aspects, wherein the gas may be introduced into the clearance from the internal block toward the inner circumferential surface of the first shell through a plurality of holes disposed in the shaft or the internal block. That is, a plurality of holes serving as the gas channel may be formed in the internal block. The gas can be introduced into the clearance though the plurality of holes.

A fifth aspect provides the substrate-conveying roller as set forth in any one of the first to third aspects, wherein the gas may be introduced into the clearance from the internal block toward the inner circumferential surface of the first shell via a manifold provided in the internal block. That is, the gas channel may include a manifold provided in the internal block. Since the gas can be introduced into the clearance via the manifold, the first shell can be cooled uniformly and efficiently.

A sixth aspect provides the substrate-conveying roller as set forth in the fifth aspect, wherein the manifold may include a plurality of manifolds arranged in a width direction of the internal block. This makes it possible to adjust pressure distribution in the clearance in a width direction of the substrate, and thus to vary the intensity of gas cooling.

A seventh aspect provides the substrate-conveying roller as set forth in the sixth aspect. The substrate-conveying roller may have the structure described below. The internal block may have a plurality of separate blocks arranged in the width direction of the substrate and corresponding to the plurality of manifolds. The first shell may have a plurality of first separate shells corresponding to the separate blocks. With this feature, an appropriate configuration of the self-cooling gas roller for the desired cooling conditions can easily be obtained by reassembling the separate blocks or the separate shells in a different way.

An eighth aspect provides the substrate-conveying roller as set forth in the seventh aspect. The substrate-conveying roller may further include a mechanism connecting each of the first separate shells to the internal block or the shaft via a bearing. Since the first shell can be firmly supported with a short span, contact between the first shell and the internal block can be prevented.

A ninth aspect provides the substrate-conveying roller as set forth in any one of the first to eighth aspects. The substrate-conveying roller may further include a second shell, a first connection mechanism, and a second connection mechanism. The second shell may be disposed between the first shell and the internal block so as to be spaced from the first shell by a gap, and may have a plurality of communicating holes for introducing the gas from the internal block to the inner circumferential surface of the first shell. The first connection mechanism may connect the second shell to the shaft via a bearing or may connect the second shell to the internal block via a bearing. The second connection mechanism may connect the first shell to the second shell via a bearing. With this configuration, abrasion damage to the substrate caused by the first shell can be prevented even during high-speed conveyance by driving and rotating the second shell using a belt, a chain, or the like.

A tenth aspect provides the substrate-conveying roller as set forth in the eighth aspect. The substrate-conveying roller may have the structure described below. The internal block may have a plurality of separate blocks arranged in a width direction of the substrate and provided separately so as to correspond to the plurality of manifolds. The second shell may have a plurality of second separate shells corresponding to the separate blocks. With this configuration, even in the case of a self-cooling gas roller of large width, it is possible to easily maintain, in particular, processing accuracy for grinding of the inner surface.

An eleventh aspect provides the substrate-conveying roller as set forth in any one of the first to tenth aspects, wherein the gas may be discharged only from an end portion of the first shell.

A twelfth aspect provides the substrate-conveying roller as set forth in any one of the first to eleventh aspects, wherein the first shell may have no through hole in a circumference thereof. According to the eleventh and twelfth aspects, the gas can efficiently be used for cooling.

A thirteenth aspect provides the substrate-conveying roller as set forth in any one of the first to twelfth aspects, wherein the internal block may have a shape of a solid cylinder or a hollow cylinder having the same central axis as the first shell. With this configuration, the width of the clearance in the radial direction of the first shell can easily be made constant.

A fourteenth aspect provides the substrate-conveying roller as set forth in any one of the first to thirteenth aspects, wherein the clearance may have a width of 0.05 to 1 mm in a region where a distance between the first shell and the internal block is smallest.

A fifteenth aspect provides the substrate-conveying roller as set forth in any one of the first to fourteenth aspects, wherein a pressure in the clearance may be 10 to 1000 Pa. According to the fourteenth and fifteenth aspects, the efficiency of heat transfer between the first shell 11 and the internal block 12 can be enhanced.

A sixteenth aspect provides the substrate-conveying roller as set forth in any one of the first to fifteenth aspects. The substrate-conveying roller may further include a leakage preventing structure for reducing gas leakage, the leakage preventing structure being disposed at a position closer to either end in a width direction of the first shell than a position at which the gas is introduced into the clearance from the internal block toward the inner circumferential surface of the first shell. That is, a leakage preventing structure may be provided at a position closer to either end in the width direction of the first shell than the position of the gas introduction. This configuration allows efficient use of the gas in cooling.

A seventeenth aspect provides the substrate-conveying roller as set forth in any one of the first to sixteenth aspects, wherein the shaft or the internal block may have a flow path in which a coolant liquid flows. With this configuration, the first shell can be cooled more efficiently.

An eighteenth aspect provides the substrate-conveying roller as set forth in the first aspect, wherein the first shell may be connected to the shaft or the internal block via a bearing. With this configuration, the first shell 11 can rotate smoothly.

A nineteenth aspect provides the substrate-conveying roller as set forth in any one of the first to eighteenth aspects, wherein an average pressure in the clearance may be lower than an atmospheric pressure when the gas has been introduced into the substrate-conveying roller placed under vacuum. By setting the average pressure in the clearance to such a pressure, the amount of the coolant gas leaked from the first shell can be reduced, and the efficiency of heat transfer between the first shell and the internal block can be enhanced without significant deterioration in the degree of vacuum in a vacuum apparatus.

The present disclosure also provides an apparatus for producing thin films, the apparatus including: a roller conveyance system including the substrate-conveying roller of any one of the first to nineteenth aspects; an opening provided in a conveyance route of the roller conveyance system; a film formation source for applying a material to the substrate at the opening; and a vacuum chamber housing the roller conveyance system and the film formation source.

According to the above disclosure, it is possible to construct a compact apparatus that can prevent deterioration in the degree of vacuum caused by use of a self-cooling free roller and that can maintain thermal stability of the free roller over a long period of time. That is, an apparatus for producing thin films that keeps thermally stable over a long period of time can be provided.

The present disclosure also provides a method for producing thin films, the method including the steps of: conveying a substrate from an unwinding position to a winding position in a roller conveyance system under vacuum; and evaporating a material from a film formation source toward an opening provided in a conveyance route of the roller conveyance system, so as to apply the material to the substrate. In the method, the roller conveyance system includes the substrate-conveying roller of any one of the first to nineteenth aspects.

According to the above disclosure, the thermal stability of a free roller can be maintained over a long period of time. Therefore, a take-up type thin film production can be carried out stably over a long period of time.

Hereinafter, embodiments of the present invention will be described with reference to the drawings. Examples of structures of substrate-conveying rollers will be described in embodiments 1 to 6. Hereinafter, a substrate-conveying roller is referred to as a self-cooling gas roller.

### Embodiment 1

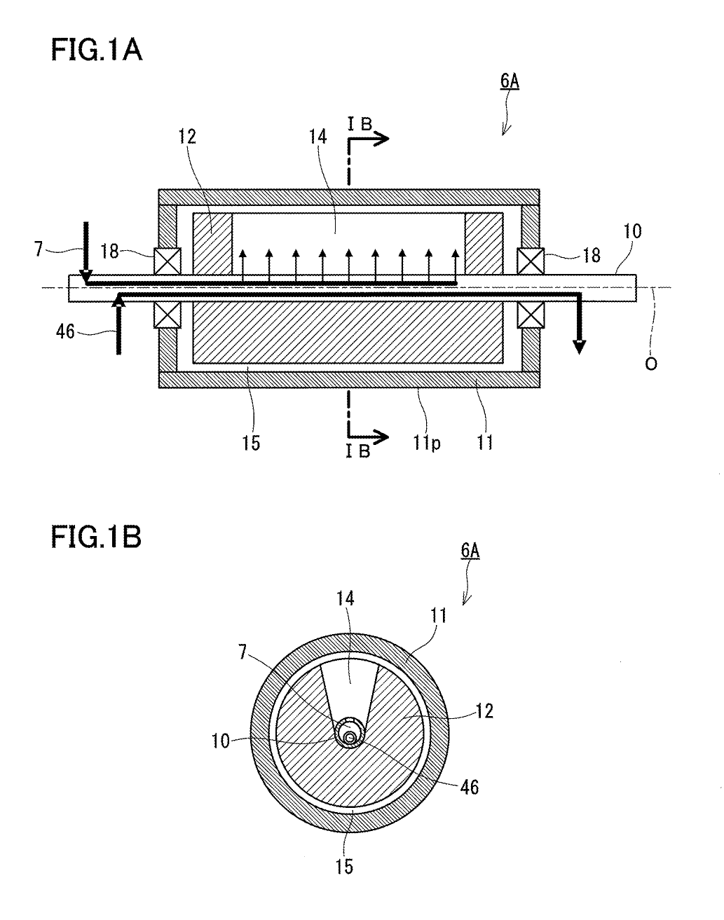

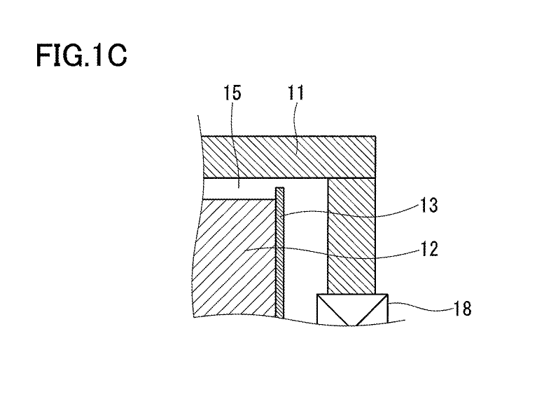

Hereinafter, an embodiment 1 of the present invention will be described with reference to FIG. 1A and FIG. 1B. A self-cooling gas roller according to the present embodiment is schematically shown in FIG. 1A and FIG. 1B.

As shown in FIG. 1A and FIG. 1B, a self-cooling gas roller 6A has a first shell 11 that rotates in synchronization with a substrate, an internal block 12 that does not rotate in synchronization with the substrate, and a shaft 10 that supports the internal block 12. The first shell 11 has a cylindrical outer circumferential surface 11p for supporting the substrate. The internal block 12 is disposed inside the first shell 11. The internal block has a solid-cylindrical or hollow-cylindrical shape as a whole. The shaft 10 extends through the internal block 12, and supports the internal block 12. The central axes O of the shaft 10 and the internal block 12 coincide with the central axis O (rotational axis) of the first shell 11.

The first shell 11 is connected to the shaft 10 via bearings 18, and rotates in synchronization with the substrate. The internal block 12 is disposed in a hollow portion of the first shell 11 having a hollow-cylindrical shape. However, the first shell 11 may be connected to the internal block 12 via the bearings 18.

A manifold 14 into which a gas is introduced, and a clearance 15 provided outside the region where the manifold 14 extends, are formed between the first shell 11 and the internal block 12.

The manifold 14 is formed by hollowing a part of the internal block 12, and is connected to a first gas flow path 7 of the internal block 12 or of the shaft 10 supporting the internal block 12.

With such a configuration, the gas can be introduced into the clearance 15 from the first gas flow path 7 in the shaft 10 via the manifold 14 provided in the internal block 12. Accordingly, the first shell 11 can be cooled uniformly and efficiently.

More specifically, when the substrate having been subjected to thermal load is conveyed by the self-cooling gas roller 6A, the first shell 11 receives some heat from the substrate within the range of a holding angle, and at the same time, can be gas-cooled by the internal block 12. In addition, outside the range of the holding angle, the first shell 11 receives no heat from the substrate, and can be gas-cooled by the internal block 12. The “holding angle” is an angle defined by the contact portion between the first shell 11 and the substrate.

As described above, while the first shell 11 is rotating, the first shell 11 intermittently repeats reception of heat from the substrate, and at the same time, is gas-cooled to release heat to the internal block 12. Therefore, unlike in the case of an ordinary conveying roller having no self-cooling function, stable cooling operation can be performed for a long period of time.

The manifold 14 is desirably disposed in such a manner that the center of the manifold 14 is located in a central region in the width direction of the first shell 11. This allows uniform cooling in the width direction. Specifically, the manifold 14 is formed in the internal block 12 so that the central region in the width direction of the first shell 11 is cooled with relatively high intensity, and the edge region in the width direction of the first shell 11 is cooled with relatively low intensity. The width direction of the first shell 11 means a direction parallel to the rotational axis O of the first shell 11 (the central axis of the shaft 10). The width direction of the first shell 11 coincides with the width direction of the substrate.

Furthermore, in the self-cooling gas roller 6A, a water flow path 46 for a coolant water for preventing temperature increase is provided in the shaft 10 for the purpose of enhancing the efficiency of cooling of the first shell 11. Cooling means is not limited to water, and a liquid or gaseous refrigerant can be used. The water flow path 46 may be formed in the internal block 12. That is, the shaft 10 and/or the internal block 12 may have a flow path in which a coolant liquid flows.

The diameter of the first shell 11 is, for example, 40 to 1000 mm. The larger the first shell 11 is, the more easily cooling performance can be obtained. However, when the first shell 11 is too large, the self-cooling gas roller 6A occupies a large volume in the vacuum chamber, and the size of a thin film production apparatus is thus increased, which leads to increase in equipment cost. In addition, since a larger diameter of the first shell 11 leads to a larger absolute value of deformation caused by thermal expansion, it is difficult to maintain the accuracy of the gap between the first shell 11 and the internal block 12 when the length of the first shell 11 in the axial direction is large. On the other hand, when the diameter of the first shell 11 is small, it is difficult to ensure the accuracy of grinding process of the inner surface of the first shell 11.

The length of the first shell 11 in the axial direction is desirably set to be larger than the width of the substrate in order to allow stable travel, and is set to, for example, 100 to 800 mm depending on the width of the substrate. The thickness of the first shell 11 is, for example, 2 to 15 mm in a region on which the substrate is conveyed. When the thickness is small, the first shell 11 is likely to be deformed by the tension of the substrate, whereas when the first shell 11 is thick, the rotation of the self-cooling gas roller 6A is sluggish. The above ranges are specified only for illustrative purposes, and the self-cooling gas roller 6A may have dimensions falling outside the ranges specified for illustrative purposes.

The gap between the first shell 11 and the internal block 12 is desirably 0.05 to 1 mm in a region where the distance between the first shell 11 and the internal block 12 is smallest. By setting such a gap, the efficiency of heat transfer between the first shell 11 and the internal block 12 can be enhanced. In other words, the width of the clearance 15 in a region where the distance between the first shell 11 and the internal block 12 is smallest may be adjusted to 0.05 to 1 mm. The width of the clearance 15 can be defined by the distance between the inner circumferential surface of the first shell 11 and the outer circumferential surface of the internal block 12.

A leakage preventing structure for reducing gas leakage is desirably disposed at a position closer to either end in the width direction of the first shell 11 than a position at which the gas is introduced into the clearance 15 from the internal block 12 toward the inner circumferential surface of the first shell 11. For example, it is conceivable that, as shown in FIG. 1C, an aluminum block or a blocking plate 13 is provided as the leakage preventing structure at an end portion of the clearance 15 in the width direction of the first shell 11 so as to oppose the outflow direction of the gas. This configuration allows efficient use of the gas in cooling. The gap between the first shell 11 and the internal block 12 in the clearance 15 is set to be smaller than the manifold 14, and has a width of, for example, 50 to 1000 μm. When the gap is too large, the degree of heat conduction via the clearance 15 is reduced, and cooling effect is less likely to be obtained. When the gap is too small, there is an increased risk that the first shell 11 and the internal block 12 contact each other due to, for example, processing accuracy or deformation by thermal expansion, thereby causing abnormal rotation or damage to the self-cooling gas roller 6A.

When the gas has been introduced into the clearance 15, the pressure in the clearance 15 is larger than, for example, the pressure outside the first shell 11 (inside the vacuum chamber). That is, the average pressure in the clearance 15 when the gas has been introduced is set to be higher than the average pressure inside the vacuum chamber, and lower than the atmospheric pressure. Desirably, the pressure (average pressure) in the clearance 15 is, for example, 10 to 1000 Pa. By setting such a pressure, the amount of the coolant gas leaking out from both ends of the first shell 11 can be reduced, and the efficiency of heat transfer between the first shell 11 and the internal block 12 can be enhanced without significant deterioration in the degree of vacuum in a vacuum apparatus. In addition, the reduction in the amount of leakage of the coolant gas also leads to reduction in load on an evacuation pump.

The pressure in the clearance 15 can be theoretically calculated from conductance of the clearance 15. Calculation is carried out for a plurality of positions in the clearance 15, and the obtained values are averaged. Thus, the average pressure can be calculated. The following operation can be performed to know the actual pressure in the clearance 15. A pressure measurement roller having the same structure as the self-cooling gas roller 6A but not capable of rotating is fabricated, and a vacuum gauge is attached to a clearance of the pressure measurement roller. The pressure measurement roller is placed under conditions in which the self-cooling gas roller 6A is actually used. A coolant gas is supplied to the pressure measurement roller, and the value indicated by the vacuum gauge is read. Thus, the actual pressure of the clearance 15 can be known.

The shaft 10 and the internal block 12 may be constructed integrally. In this case, a coolant gas introduced from the first gas flow path 7 of the shaft 10 into the manifold 14 is supplied via the manifold 14 to the clearance 15 formed by the internal block 12 and the inner circumferential surface of the first shell 11. The first gas flow path 7 may be formed in a portion corresponding to the internal block 12.

The first shell 11 has no through hole in its circumference. That is, no hole is formed in the substrate conveying surface 11p (cylindrical outer circumferential surface 11p). The gas is discharged to the outside of the first shell 11 only from an end portion of the first shell 11. In the present embodiment, the gas is discharged from the inside of the first shell 11 to the outside of the first shell 11 only through the bearings 18 (e.g., ball bearings) disposed at both end portions of the first shell 11 in a direction parallel to the rotational axis O of the first shell 11. This configuration allows efficient use of the gas in cooling.

According to the structure of the self-cooling gas roller 6A as described above, while the first shell 11 is rotating, the first shell 11 moves to face the manifold 14 and the clearance 15. The heat conduction coefficient is much larger when the first shell 11 faces the clearance 15 than when the first shell 11 faces the manifold 14. Therefore, the first shell 11 is largely cooled when the first shell 11 faces the clearance 15. Accordingly, in the case where cooling performance is given priority over the distribution of cooling intensity, the manifold 14 can be omitted as long as no problem arises in the distribution and processability.

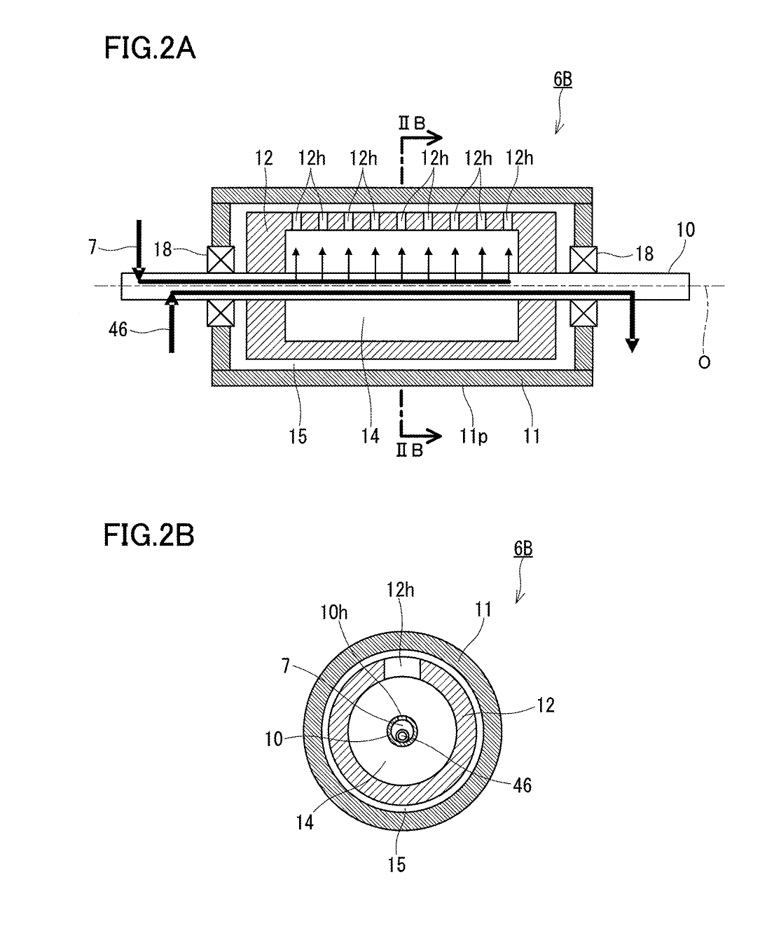

In the present embodiment, the manifold 14 is formed in the internal block 12. However, it is not essential to form the manifold 14 in the outer surface of the internal block 12. For example, as in a self-cooling gas roller 6B shown in FIG. 2A and FIG. 2B, a space (manifold 14) defined between the shaft 10 and the internal block 12 may be formed, one or more holes 12h serving as gas channels may be formed in the outermost circumference of the internal block 12, and a gas introduction port 10h connected to the manifold 14 may be allowed to communicate with the holes 12h. Also in this case, a gas can be introduced from the internal block 12 toward the inner circumferential surface of the first shell 11. The gas channel from the gas introduction port 10h to the manifold 14 may be composed of holes that are arranged in a pipe extending along the shaft 10 in the same manner as in a flute, or may have a structure formed by inserting a gas pipe up to the vicinity of the central region of the manifold 14.

(Application to Apparatus for Producing Thin Film)

The self-cooling gas roller 6A of the present embodiment can be applied to an apparatus for producing thin films. The apparatus for producing thin films has: a roller conveyance system including the self-cooling gas roller 6A described above; an opening provided in a conveyance route of the conveyance system; a film formation source for applying a material to the substrate at the opening; and a vacuum chamber housing the roller conveyance system and the film formation source. The pressure of the vacuum chamber can be reduced by an evacuation pump. This configuration allows efficient use of a coolant gas in gas cooling. Therefore, deterioration in the degree of vacuum during cooling can be prevented.

Accordingly, temperature increase in the roller is prevented, and high-quality thin films can be obtained under high vacuum. An apparatus for producing thin films of the present embodiment will be described below.

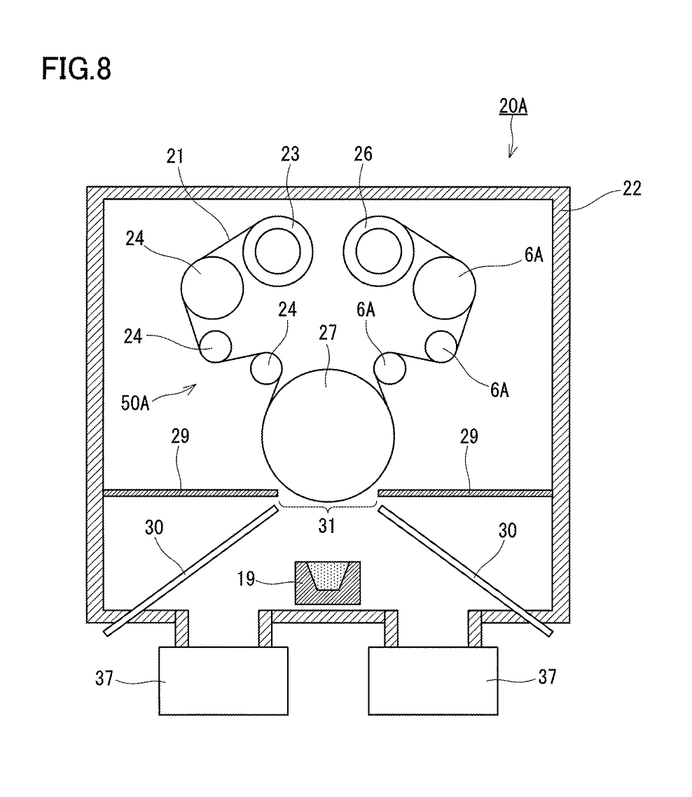

An example of an overall configuration of an apparatus 20A for producing thin films is schematically shown in FIG. 8. The vacuum chamber 22 is a pressure-resistant container member having an internal space. The internal space contains a spool roller 23, a plurality of conveying rollers 24, a spool roller 26, a can 27, self-cooling gas rollers 6A, a film formation source 19, shield plates 29, and raw material gas introduction pipes 30. The spool roller 23 is a roller member provided so as to be rotatable around an axial core. A substrate 21 having the shape of an elongated strip is wound around the surface of the spool roller 23. The spool roller 23 feeds the substrate 21 toward a conveying roller 24 that is closest to the spool roller 23.

A roller conveyance system 50A is formed of the spool roller 23 (unwinding position), the plurality of conveying rollers 24, the spool roller 26 (winding position), the can 27, and the plurality of self-cooling gas rollers 6A. The roller conveyance system 50A may have only one self-cooling gas roller 6A. The self-cooling gas roller 6B described with reference to FIG. 2A and FIG. 2B can be used instead of the self-cooling gas roller 6A. Any of the self-cooling gas rollers according to other embodiments described later can also be used instead of the self-cooling gas roller 6A. The roller conveyance system 50A may have several types of self-cooling gas rollers having different structures.

Evacuation means 37 is provided outside the vacuum chamber 22, and serves to reduce the pressure inside the vacuum chamber 22 to a pressure suitable for forming thin films. For example, the discharge means 37 is composed of any of various vacuum evacuation systems whose main pump is a vacuum pump such as an oil diffusion pump, a cryopump, and a turbo-molecular pump.

Usable as the substrate 21 are: various metal foils including aluminum foils, copper foils, nickel foils, titanium foils, and stainless steel foils; various polymer films including polyethylene terephthalate, polyethylene naphthalate, polyamide, and polyimide; a composite of a polymer film and a metal foil; and an elongated substrate made of a material other than the aforementioned materials. The width of the substrate 21 is, for example, 50 to 1000 mm. A desirable thickness of the substrate 21 is, for example, 3 to 150 μm. When the width of the substrate 21 is less than 50 mm, the productive efficiency is low. However, this does not mean that the self-cooling gas roller 6A of the present embodiment is inapplicable. When the thickness of the substrate 21 is less than 3 μm, the substrate 21 has an extremely low heat capacity, and is thus prone to thermal deformation. However, neither the extremely low heat capacity nor the proneness to thermal deformation means that the self-cooling gas roller 6A of the present embodiment is inapplicable. Although depending on the type of a thin film to be fabricated and on the conditions for film formation, the conveyance speed of the substrate 21 is, for example, 0.1 to 500 m/minute. The tension applied in the travelling direction of the substrate 21 to the substrate 21 being conveyed is selected as appropriate, depending on the material of the substrate 21, the thickness of the substrate 21, and the process conditions such as the film formation rate.

The conveying rollers 24 are each a roller member provided so as to be rotatable around an axial core. The conveying rollers 24 guide the substrate 21 fed from the spool roller 23 to a film formation region, and finally to the spool roller 26. When the substrate 21 travels along the can 27 in an opening 31 provided in the film formation region, material particles coming from the film formation source 19 react with a raw material gas introduced from the raw material gas introduction pipes 30 as necessary, and are deposited on the substrate 21. As a result, a thin film is formed on a surface of the substrate 21. The spool roller 26 is a roller member provided so as to be driven to rotate by drive means which is not shown. The substrate 21 on which a thin film has been formed is wound and stored on the spool roller 26.

Various film formation sources can be used as the film formation source 19. Examples of film formation sources that can be used include: film formation sources using resistance heating, induction heating, or electron beam heating; ion plating sources; sputtering sources; and CVD sources. In addition, an ion source or a plasma source can be used in combination with the film formation source 19. For example, the film formation source 19 is a container member provided vertically below the lowermost portion of the opening 31 and having an upper portion that is open. One specific example of the film formation source is an evaporation crucible 19. A material is placed inside the evaporation crucible 19. Heating means such as an electron gun is provided in the vicinity of the film formation source 19. The material inside the evaporation crucible 19 is heated and evaporated, for example, by an electron beam emitted from the electron gun. The vapor of the material moves vertically upward, and attaches to the surface of the substrate 21 via the opening 31, as a result of which a thin film is formed.

By the shield plates 29, the region in which material particles coming from the film formation source 19 contact the substrate 21 is limited only to the opening 31.

The apparatus 20A for producing thin films of the present embodiment may further be provided with means for introducing a film formation gas for reactive film formation into the vacuum chamber 22. One example of the means for introducing a film formation gas is the film formation reaction gas introduction pipe 30 of FIG. 8. For example, the film formation reaction gas introduction pipe 30 is a tubular member that has one end disposed vertically above the film formation source 19 and the other end provided outside the vacuum chamber 22, and that is connected to film formation reaction gas supply means which is not shown. The film formation reaction gas introduction pipe 30 supplies, for example, oxygen or nitrogen to the vapor of the material. Thus, a thin film whose main component is an oxide, a nitride, or an oxynitride of the material coming from the film formation source 19, is formed on a surface of the substrate 21. Examples of the film formation reaction gas supply means include gas cylinders and gas generators.

The substrate 21, to which the vapor coming from the film formation source 19 and oxygen or nitrogen introduced as necessary have been applied in the opening 31 and on which the thin film has been formed, travels through the self-cooling gas rollers 6A and the conveying rollers 24, and is then wound on the spool roller 26.

A method for producing thin films of the present embodiment includes the step of conveying the substrate 21 and the step of evaporating the material from the film formation source 19. Specifically, the substrate 21 is conveyed from the spool roller 23 to the spool roller 26 in the roller conveyance system 50A. The material is evaporated from the film formation source 19 toward the opening 31 provided in the conveyance route of the conveyance system 50A, and is thus applied onto the substrate 21.

The self-cooling gas roller 6A is disposed in place of the conveying roller 24 on the substrate conveyance route from one spool roller to the other spool roller. This prevents the temperature of the roller from being increased by the substrate 21 having a high temperature. Which of the conveying rollers should be the self-cooling gas roller 6A is determined as appropriate in accordance with the process specification or the like. Examples of choices include a conveying roller located immediately subsequent to the film formation region, and a conveying roller having a wide holding angle. A plurality of self-cooling gas rollers 6A may be used, and all the conveying rollers can be the self-cooling gas rollers 6A.

The increase in the heat transfer coefficient between the first shell 11 and the internal block 12 can be calculated as follows: the temperature of the surface of the self-cooling gas roller 6A, the temperature of the internal block 12, and the temperatures of the substrate before and after passing through the self-cooling gas roller 6A, are measured with thermocouples or the like; and the increase in the heat transfer coefficient is calculated from the change in the temperature of each thermocouple between when a gas is introduced and when no gas is introduced. Although depending on the type of the constituent material of the roller, the heat transfer coefficient in the gas cooling is, for example, 0.003 W/cm²/K. In addition, by flowing a larger amount of gas toward the central portion in the width direction of the film formation region than toward the edge portion of the film formation region, the intensity of cooling by the roller can be increased in the central portion in the width direction of the film formation region, and occurrence of deflection of the roller and the substrate can be prevented.

As described above, according to the apparatus 20A for producing thin films, the substrate 21 fed from the spool roller 23 travels through the conveying rollers 24 some of which may be replaced by the self-cooling gas rollers 6A, and is wound on the spool roller 26. On the route from the spool roller 23 to the spool roller 26, a vapor coming from the film formation source 19 and oxygen or nitrogen introduced as necessary are applied to the substrate 21 in the opening 31, and a thin film is formed on the substrate 21. In these operations, the apparatus 20 A for producing thin films can perform take-up type film formation in which increase in the temperature of the self-cooling gas roller 6A is reduced.

The foregoing description is given of the case where argon gas or helium gas is used as the coolant gas introduced into the self-cooling gas roller 6A. However, the coolant gas is not limited to these gases. Inert gas such as neon gas, xenon gas, and krypton gas, oxygen gas, or hydrogen gas, can be used as the coolant gas.

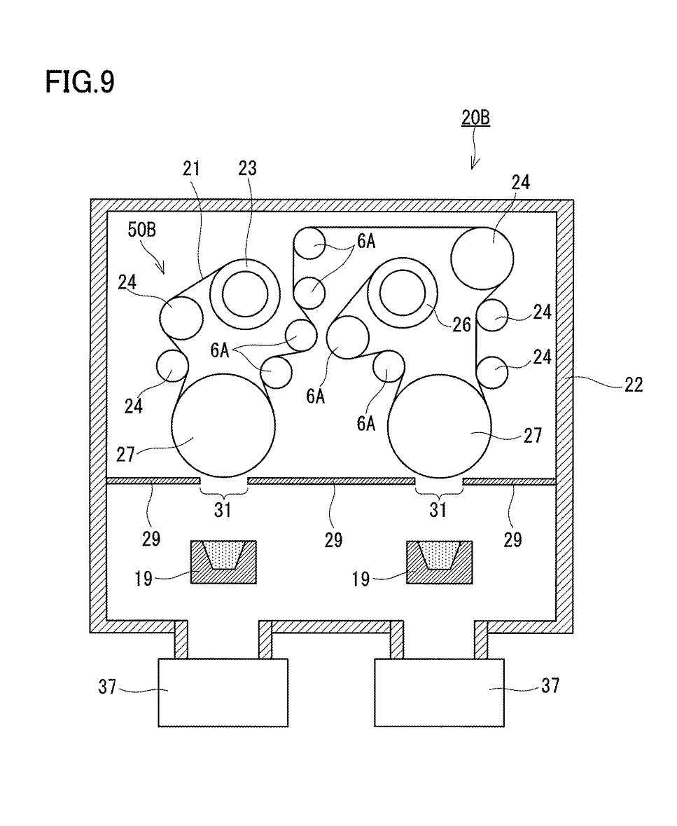

As shown in FIG. 9, an apparatus 20B for producing thin films includes a plurality of film formation sources 19, a plurality of openings 31, and a roller conveyance system 50B having a plurality of cans 27. With the roller conveyance system 50B, thin films can be formed on both surfaces of the substrate 21.

Although modes for carrying out the invention have been specifically described with reference to the drawings, the present invention is not limited thereto. The scope of the present invention encompasses another type of self-cooling gas roller and an apparatus for producing thin films using the other type of self-cooling gas roller, the other type of self-cooling gas roller having; a cylindrical first shell 11 that rotates in synchronization with the substrate 21; an internal block 12 that does not rotate in synchronization with the substrate 2; and a shaft that extends through the internal block 12. In the self-cooling gas roller, the inner circumferential surface of the first shell 11 and the internal block 12 rotate while facing each other across a gap, and a gas is introduced into the gap via the internal block 12 toward the inner circumferential surface of the first shell 11 to form a pressurized space in the gap.

In addition, the present invention can be applied to various uses for which high-speed and stable film formation is required, and specific examples of uses include electrode plates for electrochemical capacitors, transparent electrode films, capacitors, negative electrodes for lithium-ion secondary batteries, decorative films, solar cells, magnetic tapes, gas barrier membranes, various types of sensors, various types of optical membranes, and hard protective membranes. It should be understood that the present invention can be applied to thin film production apparatuses for forming various devices.

### Embodiment 2

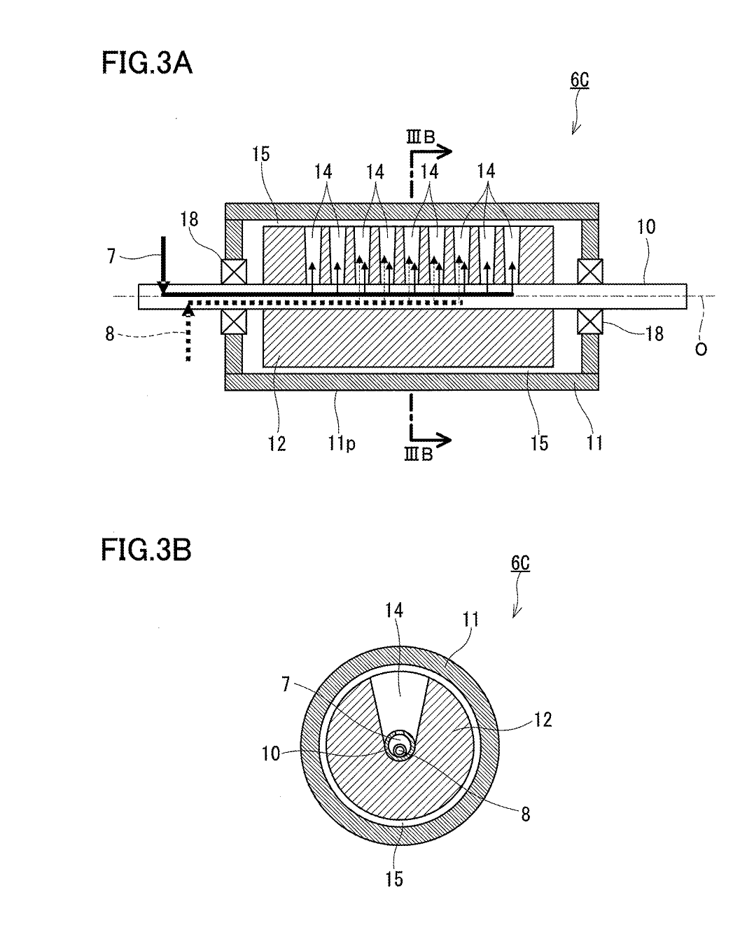

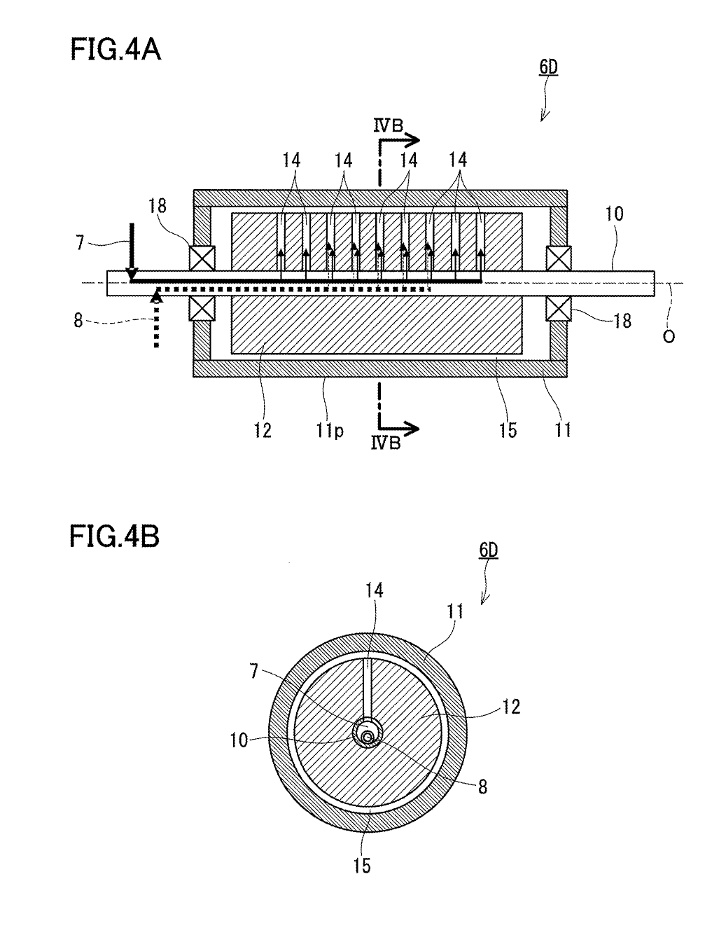

Next, an embodiment 2 will be described with reference to FIG. 3A, FIG. 3B, FIG. 4A, and FIG. 4B. The same components as those in the embodiment described above are denoted by the same reference numerals, and the description thereof is omitted.

In the present embodiment, the manifold is formed of a plurality of manifolds 14 as shown in FIG. 3A, FIG. 3B, FIG. 4A, and FIG. 4B. When the plurality of manifolds 14 are formed in this manner, the conductance of each gas flow path (manifold 14) can be independently set. The plurality of manifolds 14 are arranged in the internal block 12 in the width direction.

This configuration makes it possible to adjust the pressure distribution in the clearance 15 in the width direction of the substrate, and to vary the intensity of gas cooling.

For example, in many cases where a thin film is formed using a vacuum process, thermal load applied to the central region in the width direction of the substrate is larger than thermal load applied to the edge region in the width direction of the substrate. This is because thermal load resulting from radiation heat is larger around the center in the width direction of the substrate than in the edge region in the width direction of the substrate even when the thin film has a uniform thickness. In such a case, the conductance of the plurality of manifolds 14 disposed inside the first shell 11 is designed so that the amount of the coolant gas introduced from the manifolds 14 into the clearance 15 in the self-cooling gas roller 6C (or 6D) is increased in the central region in the width direction of the substrate. As a result, variation in the cooling intensity can be produced in accordance with thermal load applied to the substrate. This can narrow the temperature distribution in the width direction of the first shell 11, and can reduce thermal deflection of the self-cooling gas roller 6C (or 6D), thermal deflection of the substrate, and the like.

In addition, as shown in FIG. 3A, FIG. 3B, FIG. 4A, and FIG. 4B, a plurality of gas introduction ports (inlets for supplying a gas to the self-cooling gas roller) may be prepared, and gas flow paths (a first gas flow path 7 and a second gas flow path 8) to which the gas introduction ports are connected may be allowed to communicate with different manifolds. That is, the self-cooling gas roller 6C (or 6D) has the first gas flow path 7 and the second gas flow path 8. The first gas flow path 7 is a flow path formed inside the shaft 10 so as to allow a gas to be supplied from the outside of the first shell 11 to at least one of the manifolds 14. The second gas flow path 8 is a flow path formed inside the shaft 10 so as to allow a gas to be supplied from the outside of the first shell 11 to at least one of the manifolds 14.

In addition, the types of gases introduced can be different between the first gas flow path 7 and the second gas flow path 8. For example, in the case where high thermal load is applied to the central region in the width direction of the substrate, heat is most likely to be accumulated in the central region in the width direction of the first shell 11. In such a case, for example, argon gas may be used for the first gas flow path 7 leading to both ends of the first shell 11, and helium gas which is expensive but which allows cooling performance to be easily obtained may be used for the second gas flow path 8 leading to the central region of the first shell 11. This makes it possible to cool the self-cooling gas roller 6C (or 6D) focusing on the central region in the width direction and its vicinity.

According to the structures of the self-cooling gas rollers 6C and 6D as described above, while the first shell 11 is rotating, the first shell 11 moves to face the manifolds 14 and the clearance 15.

The heat conduction coefficient in the gas cooling is much larger when the first shell 11 faces the clearance 15 than when the first shell 11 faces the manifolds 14. Therefore, the first shell 11 is largely cooled when the first shell 11 faces the clearance 15. Accordingly, in the case where cooling performance is given priority over the distribution of cooling intensity, the manifolds 14 may not be fan-shaped as shown in FIG. 4A and FIG. 4B, as long as no problem arises in the distribution and processability. That is, each manifold 14 may be a long hole that is formed in the internal block 12 so as to extend from the shaft 10 radially outward and that has a constant diameter.

In addition, with the configuration of the present embodiment in which the plurality of manifolds 14 are formed in the width direction of the substrate, the optimal conditions for cooling in the width direction of the substrate can be achieved. Therefore, even when the amount of the coolant gas introduced is reduced, a region where the gas pressure is high can be locally formed between the first shell 11 and the internal block 12. In addition, since the self-cooling gas rollers 6C and 6D of the present embodiment can fulfill the cooling function on a compact scale, increase in the size of equipment and increase in the cost can be prevented.

The present embodiment can be applied to thin film production apparatuses similar to the embodiment 1.

### Embodiment 3

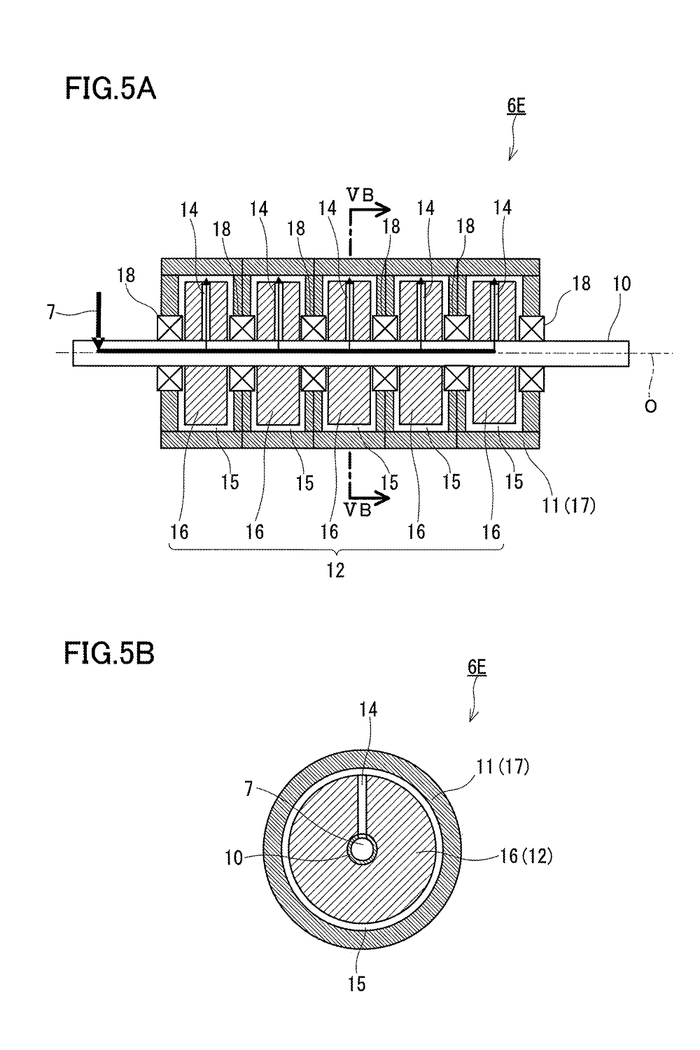

Next, an embodiment 3 will be described with reference to FIG. 5A and FIG. 5B. The same components as those described in the other embodiments are denoted by the same reference numerals, and the description thereof is omitted.

As shown in FIG. 5A and FIG. 5B, in a self-cooling gas roller 6E, the internal block 12 is constituted by a plurality of separate blocks 16 arranged in the width direction of the substrate and provided separately for each manifold 14. The plurality of separate blocks 16 respectively correspond to the plurality of manifolds 14.

Furthermore, the first shell 11 is constituted by a plurality of separate shells 17 corresponding to the separate blocks 16.

When the internal block 12 and the first shell 11 are separated into a plurality of parts, an appropriate configuration of the self-cooling gas roller for the desired cooling conditions can easily be obtained by reassembling the separate blocks 16 or the separate shells 17 in a different way. Furthermore, even in the case of a self-cooling gas roller of large width, it is possible to easily maintain, in particular, processing accuracy for grinding of the inner surface.

Furthermore, the first shell 11 can be firmly supported with a short span by connecting each of the plurality of first separate shells 11 via the bearings 18 to the internal block 12 or the shaft 10 supporting the internal block 12. Therefore, contact between the first shell 11 and the internal block 12 can be prevented. That is, the self-cooling gas roller 6E may have a mechanism connecting the first separate shells 11 to the shaft 10 or may have a mechanism connecting the first separate shells 11 to the internal block 12. Such a mechanism typically includes the bearings 18, a rotational bush, and the like. Such a mechanism may be the bearing 18 itself.

For example, in many cases where a thin film is formed using a vacuum process, thermal load applied to the central region in the width direction of the substrate is larger than thermal load applied to the edge region in the width direction of the substrate. This is because thermal load resulting from radiation heat is larger around the center in the width direction of the substrate than in the edge region in the width direction of the substrate even when the thin film has a uniform thickness.

In such a case, the conductance of the plurality of manifolds 14 disposed inside the first shell 11 is designed so that the amount of the coolant gas introduced from the manifolds 14 into the clearance 15 in the self-cooling gas roller 6E is increased in the central region in the width direction of the substrate. As a result, variation in the cooling intensity can be produced in accordance with thermal load applied to the substrate. This can narrow the temperature distribution of the first shell 11 in the width direction, and can reduce thermal deflection of the self-cooling gas roller 6E, thermal deflection of the substrate, and the like.

According to the structure of the self-cooling gas roller 6E as described above, while the first shell 11 is rotating, the first shell 11 moves to face the manifolds 14 and the clearance 15.

The heat conduction coefficient in the gas cooling is much larger when the first shell 11 faces the clearance 15 than when the first shell 11 faces the manifolds 14. Therefore, the first shell 11 is largely cooled when the first shell 11 faces the clearance 15. Accordingly, in the case where cooling performance is given priority over the distribution of cooling intensity, the manifolds 14 can be omitted as long as no problem arises in the distribution and processability.

In addition, with the configuration of the present embodiment in which the plurality of manifolds 14 are formed in the width direction of the substrate, the optimal conditions for cooling in the width direction of the substrate can be achieved. Therefore, even when the amount of the coolant gas introduced is reduced, a region where the gas pressure is high can be locally formed between the first shell 11 and the internal block 12. In addition, since the self-cooling gas roller 6E of the present embodiment can fulfill the cooling function on a compact scale, increase in the size of equipment and increase in the cost can be prevented.

The present embodiment can be applied to thin film production apparatuses similar to the embodiment 1.

### Embodiment 4

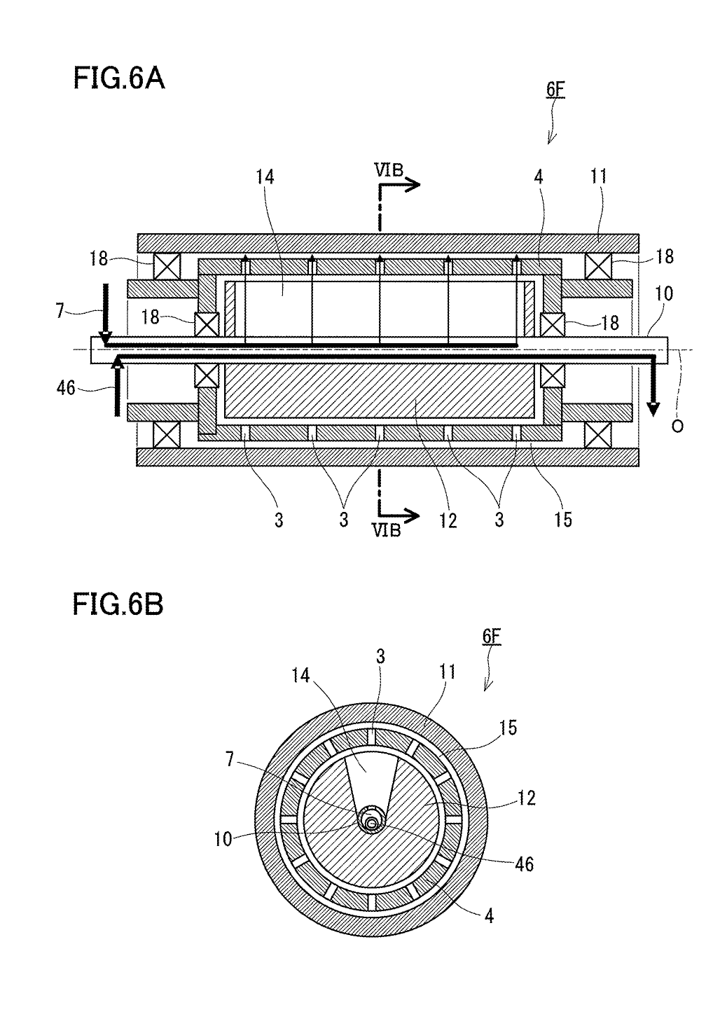

Next, an embodiment 4 will be described with reference to FIG. 6A and FIG. 6B. The same components as those described in the other embodiments are denoted by the same reference numerals, and the description thereof is omitted.

As shown in FIG. 6A and FIG. 6B, in a roller 6F of the present embodiment, a second shell 4 is disposed between the first shell 11 and the internal block 12 so as to be spaced from the first shell 11 and the internal block 12 by gaps. A plurality of communicating holes 3 for introducing a coolant gas from the manifold 14 of the internal block 12 to the inner circumferential surface of the first shell 11 are formed in the second shell 4. The number of the communicating holes 3 is not limited to two or more. Only one communicating hole 3 may be formed in the second shell 4.

According to the structure of the self-cooling gas roller 6F as described above, while the first shell 11 is rotating, the first shell 11 moves to face the manifold 14 and the clearance 15 across the second shell 4.

The heat conduction coefficient in the gas cooling is much larger when the first shell 11 faces the clearance 15 than when the first shell 11 faces the manifold 14. Therefore, the second shell 4 is largely cooled when the first shell 11 faces the clearance 15. Accordingly, in the case where cooling performance is given priority over the distribution of cooling intensity, the manifold 14 can be omitted as long as no problem arises in the distribution and processability.

The present embodiment can be applied to thin film production apparatuses similar to the embodiment 1.

### Embodiment 5

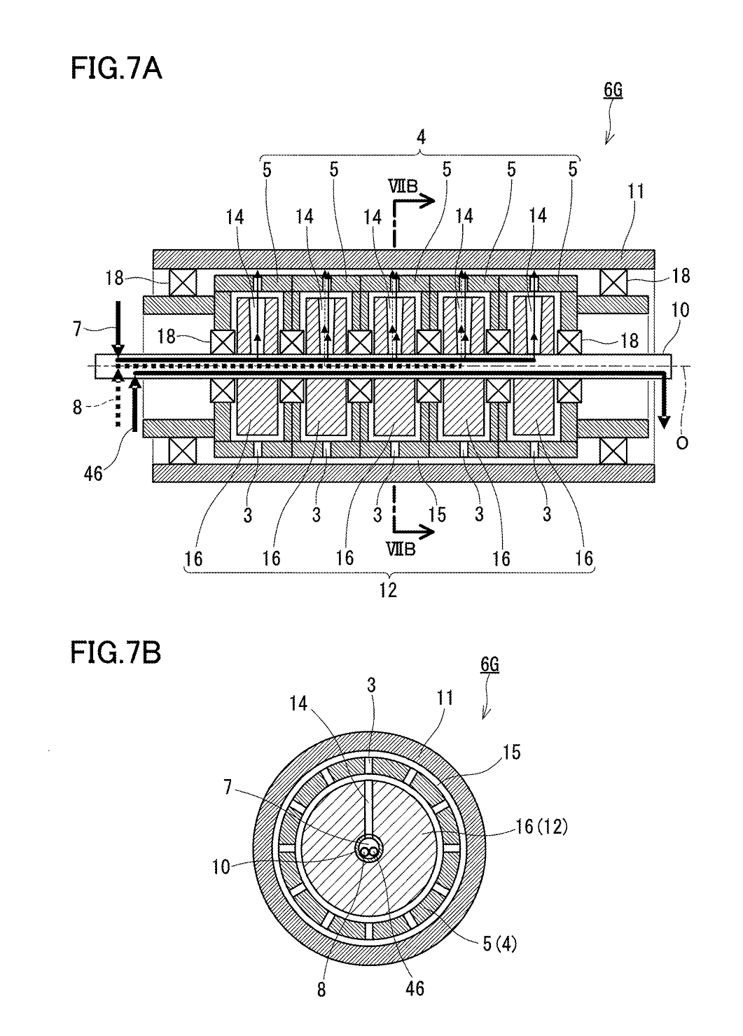

Next, an embodiment 5 will be described with reference to FIG. 7A and FIG. 7B. The same components as those described in the other embodiments are denoted by the same reference numerals, and the description thereof is omitted.

As shown in FIG. 7A and FIG. 7B, the second shell 4 is disposed between the first shell 11 and the internal block 12 so as to be spaced from the first shell 11 and the internal block 12 by gaps. A plurality of communicating holes 3 for introducing a coolant gas from the manifolds 14 of the internal block 12 to the inner circumferential surface of the first shell 11 are formed in the second shell 4.

In addition, the internal block 12 is constituted by a plurality of separate blocks 16 arranged in the width direction of the substrate and provided separately for each manifold 14.

The second shell 4 is formed by a plurality of second separate shells 5 corresponding to the separate blocks forming the internal block 12. Thus, even in the case of a self-cooling gas roller of large width, it is possible to easily maintain, in particular, processing accuracy for grinding of the inner surface. In addition, the second shell 4 can be rotatably connected via the bearings 18 to the internal block 12 or the shaft fixing the internal block 12, and the first shell 11 and the second shell 4 can be rotatably connected to each other via the bearings 18. Therefore, abrasion damage to the substrate caused by the first shell 11 can be prevented even during high-speed conveyance by driving and rotating the second shell 4 using a belt, a chain, or the like. That is, the self-cooling gas roller 6G may include a first connection mechanism connecting the second shell 4 to the shaft 10 via the bearings 18 or connecting the second shell 10 to the internal block 12 via the bearings 18, and a second connection mechanism connecting the first shell 11 to the second shell 10 via the bearings 18. The same applies to the self-cooling gas roller 6F described with reference to FIG. 6A and FIG. 6B. Specific examples of the first connection mechanism and the second connection mechanism are the same mechanisms as described in the embodiment 3.

When the internal block 12 or the second shell 4 is separated into a plurality of parts, an appropriate configuration of the self-cooling gas roller for the desired cooling conditions can easily be obtained by reassembling the separate blocks 16 or the separate shells 17 in a different way. Furthermore, even in the case of a self-cooling gas roller of large width, it is possible to easily maintain, in particular, processing accuracy for grinding of the inner surface.

Furthermore, the first shell 4 can be firmly supported with a short span by connecting each of the plurality of separate shells via the bearings 18 to the internal block 12 or the shaft 10 supporting the internal block 12. Therefore, contact between the second shell 4 and the internal block 12 can be prevented.

In addition, a plurality of gas introduction ports (inlets for supplying a gas to the self-cooling gas roller) may be prepared, and gas flow paths (a first gas flow path 7 and a second gas flow path 8) to which the gas introduction ports are connected may be allowed to communicate with different manifolds 14. In addition, the types of gases introduced can be different between the first gas flow path 7 and the second gas flow path 8. For example, in the case where high thermal load is applied to the central region in the width direction of the substrate, heat is most likely to be accumulated in the central region in the width direction of the first shell 11. In such a case, for example, argon gas may be used for the first gas flow path 7 leading to both ends of the first shell 11, and helium gas which is expensive but which allows cooling performance to easily obtained may be used for the second gas flow path 8 leading to the central region of the first shell 11. This makes it possible to cool the self-cooling gas roller 6G focusing on the central region in the width direction and its vicinity.

For example, in many cases where a thin film is formed using a vacuum process, thermal load applied to the central region in the width direction of the substrate is larger than thermal load applied to the edge region in the width direction of the substrate. This is because thermal load resulting from radiation heat is larger around the center in the width direction of the substrate than in the edge region in the width direction of the substrate even when the thin film has a uniform thickness. In such a case, the conductance of the plurality of manifolds 14 disposed inside the first shell 11 is designed so that the amount of the coolant gas introduced from the manifolds 14 into the clearance 15 in the self-cooling gas roller 6G is increased in the central region in the width direction of the substrate. As a result, variation in the cooling intensity can be produced in accordance with thermal load applied to the substrate. This can narrow the temperature distribution of the first shell 11 in the width direction, and can reduce thermal deflection of the self-cooling gas roller 6G, thermal deflection of the substrate, and the like.

According to the structure of the self-cooling gas roller 6G as described above, while the first shell 11 is rotating, the first shell 11 moves to face the manifold 14 and the clearance 15 across the second shell 4. The heat conduction coefficient in the gas cooling is much larger when the first shell 11 faces the clearance 15 than when the first shell 11 faces the manifold 14. Therefore, the second shell 4 is largely cooled when the first shell 11 faces the clearance 15. Accordingly, in the case where cooling performance is given priority over the distribution of cooling intensity, the manifolds 14 can be omitted as long as no problem arises in the distribution and processability.

With the configuration of the present embodiment in which the plurality of manifolds 14 are formed in the width direction of the substrate, the optimal conditions for cooling in the width direction of the substrate can be achieved. Therefore, even when the amount of the coolant gas introduced is reduced, a region where the gas pressure is high can be locally formed between the first shell 11 and the internal block 12. In addition, since the self-cooling gas roller 6G of the present embodiment can fulfill the cooling function on a compact scale, increase in the size of equipment and increase in the cost can be prevented.

The present embodiment can be applied to thin film production apparatuses similar to the embodiment 1.

### INDUSTRIAL APPLICABILITY

The substrate-conveying rollers and the thin film production apparatuses disclosed in the present specification have structures in which a rotating shell of a free roller is controlled by gas cooling in the width direction of the substrate, and is efficiently used. Therefore, an introduced gas is allowed to contribute to cooling of the shell without waste. In addition, a thin film production apparatus that allows cooling effect symmetrical in the width direction of the roller to be easily obtained, that causes no defect due to uneven cooling, and that can achieve high film formation rate and high quality, can be constructed at a low cost without increase in the size of equipment such as an evacuation pump.

1-21. (canceled)

22. A substrate-conveying roller that conveys a substrate under vacuum, the substrate-conveying roller comprising:
a cylindrical first shell having a cylindrical outer circumferential surface for supporting the substrate, the cylindrical first shell being capable of rotating in synchronization with the substrate;
an internal block disposed inside the first shell and blocked from rotating in synchronization with the substrate; and
a shaft extending through, and supporting the internal block, wherein
a clearance is formed between an inner circumferential surface of the first shell and an outer circumferential surface of the internal block,
a gas is introduced into the clearance from the internal block toward the inner circumferential surface of the first shell,
the shaft or the internal block has a flow path in which a coolant liquid flows,
the internal block has a shape of a solid cylinder or a hollow cylinder, and
the clearance has a width of 0.05 to 1 mm, the width being defined by a distance between the inner circumferential surface of the first shell and the outer circumferential surface of the internal block.

23. The substrate-conveying roller according to claim 22, wherein a pressure in the clearance is higher than a pressure outside the first shell.

24. The substrate-conveying roller according to claim 22, wherein a position at which the gas is introduced into the clearance from the internal block toward the inner circumferential surface of the first shell is located in a central region in a width direction of the first shell.

25. The substrate-conveying roller according to claim 22, wherein
the gas is introduced into the clearance from the internal block toward the inner circumferential surface of the first shell through a plurality of holes disposed in the shaft or the internal block, and
the plurality of holes are formed along an axial direction of the shaft or the internal block.

26. The substrate-conveying roller according to claim 22, wherein the gas is introduced into the clearance from the internal block toward the inner circumferential surface of the first shell via a manifold provided in the internal block.

27. The substrate-conveying roller according to claim 26, wherein the manifold includes a plurality of manifolds arranged in a width direction of the internal block.

28. The substrate-conveying roller according to claim 27, wherein
the internal block has a plurality of separate blocks arranged in a width direction of the substrate and corresponding to the plurality of manifolds, and
the first shell has a plurality of first separate shells corresponding to the separate blocks.

29. The substrate-conveying roller according to claim 28, further comprising a mechanism connecting each of the first separate shells to the internal block or the shaft via a bearing.

30. The substrate-conveying roller according to claim 22, further comprising:
a second shell disposed between the first shell and the internal block so as to be spaced from the first shell by a gap, and having a plurality of communicating holes for introducing the gas from the internal block to the inner circumferential surface of the first shell;
a first connection mechanism connecting the second shell to the shaft via a bearing or connecting the second shell to the internal block via a bearing; and
a second connection mechanism connecting the first shell to the second shell via a bearing.

31. The substrate-conveying roller according to claim 29, wherein
the internal block has a plurality of separate blocks arranged in a width direction of the substrate and provided separately so as to correspond to the plurality of manifolds, and
the second shell has a plurality of second separate shells corresponding to the separate blocks.

32. The substrate-conveying roller according to claim 22, wherein the gas is discharged only from an end portion of the first shell.

33. The substrate-conveying roller according to claim 22, wherein the first shell has no through hole in a circumference thereof.

34. The substrate-conveying roller according to claim 22, wherein a pressure in the clearance is 10 to 1000 Pa.

35. The substrate-conveying roller according to claim 22, further comprising a leakage preventing structure for reducing gas leakage, the leakage preventing structure being disposed at a position closer to either end in a width direction of the first shell than a position at which the gas is introduced into the clearance from the internal block toward the inner circumferential surface of the first shell.

36. The substrate-conveying roller according to claim 22, wherein
the first shell is connected to the shaft or the internal block via a bearing,
the bearing is disposed at an end portion of the first shell, and
the gas is discharged outside the first shell only through the bearing.

37. The substrate-conveying roller according to claim 22, wherein an average pressure in the clearance is lower than an atmospheric pressure when the gas has been introduced into the substrate-conveying roller placed under vacuum.

38. An apparatus for producing thin films, comprising:
a roller conveyance system including the substrate-conveying roller according to claim 22;
an opening provided in a conveyance route of the roller conveyance system;
a film formation source for applying a material to the substrate at the opening; and
a vacuum chamber housing the roller conveyance system and the film formation source.

39. A method for producing thin films, comprising steps of:
conveying a substrate from an unwinding position to a winding position in a roller conveyance system under vacuum; and
evaporating a material from a film formation source toward an opening provided in a conveyance route of the roller conveyance system, so as to apply the material to the substrate,
wherein the roller conveyance system includes the substrate-conveying roller according to claim 22.

40. The substrate-conveying roller according to claim 30, wherein the gas is discharged outside the first shell and the second shell only though the bearings of the first connection mechanism and the second connection mechanism.
